(19) United States
(12) Patent Application Publication
(10) Pub. No.: US 2015/0366105 A1
(43) Pub. Date: Dec. 17, 2015

(54) CONFIGURABLE HEAT TRANSFER GRIDS AND RELATED METHODS

(71) Applicant: Birchbridge Incorporated, Belmont, CA (US)

(72) Inventors: John Craig Dunwoody, Belmont, CA (US); Teresa Ann Dunwoody, Belmont, CA (US)

(21) Appl. No.: 14/302,925

(22) Filed: Jun. 12, 2014

(51) Int. Cl. H05K 7/20; B23P 15/26

(52) U.S. Cl. CPC H05K 7/20509; H05K 7/20336; B23P 15/26

(57) ABSTRACT

Configurable heat transfer grids that provide cooling to computing components are discussed herein. Some embodiments may include a configurable heat transfer grid comprising a cooling frame and one or more cooling elements. The cooling frame may define a plurality of receptacles that are each configured to receive one or more cooling elements. The one or more cooling elements may include an elongated shape and may be configured to be disposed within one or more of the plurality of receptacles, such as through apertures at outer ends of the cooling frame. The cooling elements may include heat pipes and/or heat spreaders. Some embodiments may provide for configurable heat transfer grids that include split cooling frames that can be opened for cooling element placement. Some embodiments may further provide for configuring a configurable heat transfer grid to implement effective and inexpensive heat removal for a wide range of specific printed circuit board assembly (PCBA) layouts, dimensions, and component types.

### FIELD

Embodiments of the invention relate, generally, to systems and methods for cooling board mounted electronic components.

### BACKGROUND

Circuitry can be configured to provide data networking, processing, storage, and/or other types of functionality. Often, such circuitry, which typically includes various different components, is mounted on boards used in computing systems, and such boards may be installed in computing racks that may provide packaging, power, networking and cooling. The design of these rack-based type computing systems may require various tradeoffs in areas such as space efficiency, energy efficiency, cost, scalability, configurability, and serviceability. In this regard, opportunities for improving current systems have been identified, including reductions in space requirements and energy consumption. These opportunities include improvements in component cooling, which in current systems requires very significant amounts of space and energy.

### BRIEF SUMMARY

Through applied effort, ingenuity, and innovation, solutions to improve rack-based types of computing systems that may perform data-related functions and/or other types of functions, have been realized and are described herein, including improvements in cooling. Some embodiments may include a self-contained heat transfer grid. The heat transfer grid may include: a cooling frame, the cooling frame defining a first cooling plane and a second cooling plane and having a first outer end and a second outer end, each of the first outer end and the second outer end including one or more apertures that define a plurality of receptacles between the first and second cooling planes; and one or more removable cooling elements, the one or more cooling elements having an elongated shape and positionable within one or more of the plurality of receptacles.

In some embodiments, the heat transfer grid may further include at least one external heat exchange interface region on one of the first or second cooling planes. A first one of the one or more cooling elements positioned within one of the plurality of receptacles may extend from one of the first or second outer ends to the external heat exchange interface region.

In some embodiments, each of the plurality of receptacles may have a cross sectional shape that is substantially the same as a cross sectional shape of the one or more removable cooling elements, and may include an elongated shape defining an elongated direction. The cooling frame may include at least two receptacles, and the one or more removable cooling elements may be positioned in fewer than all of the at least two receptacles.

In some embodiments, the heat transfer grid may include at least three external heat exchange interface regions. At least a first one of the external heat exchange interface regions may be adjacent to and parallel to the first outer end. At least a second one of the external heat exchange interface regions may be adjacent to and parallel to the second outer end. In some embodiments, the first cooling element may not extend from the first outer end to the second outer end of the cooling frame when positioned within the receptacle.

In some embodiments, the first cooling element may be positioned within one of the receptacles and may extend only part way from the first outer end of the cooling frame to the second outer end. A second one of the one or more cooling elements may be positioned within the same receptacle as the first cooling element, and may extend only part way from the second outer end of the cooling frame to the first outer end. The first and second cooling elements may not overlap.

In some embodiments, the first cooling element when positioned within one of the receptacles may extend from an external heat exchange interface region to a component thermal interface region of the heat transfer grid.

Some embodiments may provide for a heat transfer grid including a split cooling frame. The split cooling frame may include a first contoured component and a second contoured component. The first contoured component and the second contoured component may be configured to be removably placed together. The first contoured component and the second countered component may each include a plurality of channels. The channels in the first contoured component and the second contoured component may be arranged such that when the first contoured component and the second contoured component are placed together, the channels form elongated receptacles. The heat transfer grid may further include one or more cooling elements. The one or more cooling elements may have an elongated shape. The plurality of channels of at least one of the first contoured component and the second contoured component may be configured to receive the one or more cooling elements when the first contoured component is separated from the second contoured component, such that the one or more cooling elements can be disposed in one or more receptacles when the first contoured component and the second contoured component are placed together.

In some embodiments, the elongated receptacles may have a cross sectional shape that is substantially the same as a cross sectional shape of the one or more removable cooling elements, and may include an elongated shape defining an elongated direction. The receptacles collectively may span part or all of a width of the cooling frame, the width defined perpendicular to the elongated direction. The one or more cooling elements may be positioned and/or disposed in fewer than all of the elongated receptacles.

In some embodiments, the channels may include channel surfaces. The heat transfer grid may further include a thermal interface material disposed between at least one of the one or more cooling elements and the channel surfaces.

In some embodiments, the split cooling frame may include a first outer end and a second outer end. A first cooling element of the one or more cooling elements, when received into one of the receptacles, may not extend from the first outer end to the second outer end of the split cooling frame. In some embodiments, a first cooling element and a second cooling element of the one or more cooling elements may be received into one of the elongated receptacles.

In some embodiments, the first contoured component may include a first cooling plane including an external heat exchange interface region and a component thermal interface region. A first cooling element of the one or more cooling elements may extend from the external heat exchange interface region to the component thermal interface region.

In some embodiments, at least one receptacle associated with a non-component thermal interface region of the heat transfer grid may not include a cooling element.

Some embodiments may provide for a heat transfer grid including an open cooling frame. The open cooling frame may include: a first element guide defining a first outer edge of the open cooling frame, the first element guide including one or more apertures; and a second element guide defining a second outer edge of the open cooling frame, the second element guide including one or more apertures, such that the apertures of the first and second element guides may be collinear. The heat transfer grid may further include one or more cooling elements, each having an elongated shape and each disposed in an aperture of at least one of the first element guide and the second element guide.

In some embodiments, the open cooling frame may further include one or more guide supports. The guide supports may connect the first element guide and the second element guide. The first element guide, the second element guide, and the one or more guide supports of the open cooling frame may define a cooling element access region where the one or more cooling elements are exposed by the open cooling frame when the one or more cooling elements are each disposed in the aperture of at least one of the first element guide and the second element guide. The one or more cooling elements may include two or more cooling elements that define a cooling plane at the cooling element access region

In some embodiments, the heat transfer grid may further include an adjustable element guide configured to be connected to the one or more guide supports at variable locations between the first element guide and the second element guide. The adjustable element guide may include one or more apertures that are collinear with the apertures of the first and second element guides.

In some embodiments, at least one of the one or more cooling elements may include a flattened circular cross section. In some embodiments, at least one of the one or more cooling elements may extend beyond at least one of the first outer edge and the second outer edge of the open cooling frame. In some embodiments, at least one of the one or more cooling elements may not extend from the first outer end to the second outer end of the open cooling frame. In some embodiments, at least one of the one or more cooling elements may extend approximately half the distance from the first outer edge to the second outer edge of the cooling frame.

In some embodiments, a first one of the one or more cooling elements may include a heat pipe disposed within a first aperture of the first element guide. A second one of the one or more cooling elements may include a heat spreader disposed within a second aperture of the first element guide, the first aperture being adjacent to the second aperture.

In some embodiments, a first one of the one or more cooling elements may include a heat pipe disposed within a first aperture of the first element guide. A second one of the one or more cooling elements may include a heat spreader disposed within a second aperture of the first element guide, such that the heat pipe may be associated with a component thermal interface region of the heat transfer grid. The heat spreader may be associated with a non-component thermal interface region of the heat transfer grid.

Some embodiments may provide for a method of configuring and/or reconfiguring a heat transfer grid. The method may include: providing a heat transfer grid defining a plurality of receptacles, each receptacle being configured to receive a cooling element; determining a component interface region of the heat transfer grid; determining an external heat exchange interface region of the heat transfer grid; and disposing a cooling element within a receptacle extending from the component interface region to the external heat exchange interface region.

In some embodiments, the receptacle may be accessible via an aperture at an outer end of a cooling frame of the heat transfer grid. Disposing the cooling element within the receptacle may include disposing the cooling element within the receptacle through the aperture.

In some embodiments, disposing the cooling element within the receptacle may include: separating a first contoured component of the cooling frame from a second contoured component of the cooling frame, the first contoured component and the second contoured component being configured to be removably placed together, the first contoured component including a plurality of channels, the second contoured component including a plurality of channels, and the channels in the first contoured component and the second contoured component being arranged such that when the first contoured component and the second contoured component are placed together, the channels form the plurality of receptacles; disposing the cooling element within a channel of at least one of the first contoured component and the second contoured component; and subsequent to disposing the cooling element within the channel, joining the first contoured component with the second contoured component to form the receptacle.

In some embodiments, the channels may include channel surfaces. The method may further include, prior to joining the first contoured component with the second contoured component, disposing a thermal interface material between the cooling element and the channel surfaces.

In some embodiments, the method may further include disposing a second cooling element within a second receptacle of the plurality of receptacles, wherein the first cooling element is a heat pipe and the second cooling element is a heat spreader.

In some embodiments, the method may further include: determining a non-component interface region of the heat transfer grid; and removing a second cooling element from a second receptacle associated with the non-component interface region. In some embodiments, the method may further include, subsequent to removing the second cooling element from the second receptacle associated with the non-component interface region, disposing a third cooling element within the second receptacle, wherein the second cooling element is a heat pipe and the third cooling element is a heat spreader.

In some embodiments, determining the component interface region of the heat transfer grid may include: securing a printed circuit board assembly (PCBA) to the heat transfer grid; and determining the component interface region as a region of the heat transfer grid in thermal contact with one or more components of the PCBA when the PCBA is secured to the heat transfer grid.

In some embodiments, the method may further include: determining whether or not the cooling element can be removed from the receptacle while maintaining sufficient cooling for the PCBA by the heat transfer grid; and in response to determining that removing the cooling element would result in sufficient cooling, removing the cooling element from the receptacle.

In some embodiments, the method may further include: determining whether or not the cooling element should be added to the receptacle in order to achieve sufficient cooling for the PCBA by the heat transfer grid; and in response to determining that the cooling element should be added in order to achieve sufficient cooling, disposing the cooling element within the receptacle.

These improvements, as well as additional features, functions, and details of various corresponding and additional embodiments, are also described herein.

### BRIEF DESCRIPTION OF THE DRAWINGS

Having thus described some embodiments in general terms, reference will now be made to the accompanying drawings, which are not necessarily drawn to scale, and wherein:

FIGS. 1A-1C show examples of a configurable heat transfer grid in accordance with some embodiments;

FIGS. 2A-2C show examples of a configurable heat transfer grid including a split cooling frame in accordance with some embodiments;

FIGS. 3A-3C show examples of a configurable heat transfer grid including an open cooling frame in accordance with some embodiments;

FIG. 4A shows an example of a method for configuring a configurable heat transfer grid in accordance with some embodiments;

FIG. 4B shows an example of a method for reconfiguring a configurable heat transfer grid in accordance with some embodiments;

FIGS. 5A-5C show schematic top views of examples of a configurable heat transfer grid in accordance with some embodiments;

FIG. 6 shows a front view of an example of a system in accordance with some embodiments;

FIG. 7 shows a cross-sectional front view of an example of an edge-coolable module in accordance with some embodiments;

FIG. 8 shows a configurable heat transfer grid including thermal bridges and thermal risers in accordance with some embodiments;

FIG. 9 shows schematic top and bottom views of an example configurable heat transfer grid in accordance with some embodiments; and

FIG. 10 shows a schematic top view of an example modular configurable heat transfer grid in accordance with some embodiments.

### DETAILED DESCRIPTION

Embodiments will be described more fully hereinafter with reference to the accompanying drawings, in which some, but not all embodiments contemplated herein are shown. Indeed, various embodiments may be implemented in many different forms and should not be construed as limited to the specific embodiments set forth herein; rather, these embodiments are provided so that this disclosure will satisfy applicable legal requirements. Like numbers refer to like elements throughout. Various methods discussed herein are described with respect to flowcharts. It is appreciated that the order of steps represented in the flowcharts does not imply a required order, and that only some of the steps may be performed in various embodiments.

Conventional rack-based type computing systems provide cooling (among other things) to heat generating (e.g., computing) components using support infrastructures that are tailored and fixed to the particular dimensions and cooling requirements of the components. In such systems, the supporting infrastructure typically becomes obsolete at a rate that corresponds with the redesign, breakdown, or obsolescence of the computing components. If the supporting infrastructure could instead be designed to be more efficient and adaptable, such that the infrastructure could accommodate multiple successive generations of computing components, the effective operational lifetime of such infrastructure could be extended very significantly, yielding many benefits including reductions in costs and environmental burdens associated with energy consumption, raw-materials usage, and waste disposal. Some embodiments discussed herein may provide for configurable heat transfer grids directed to these and other technical problems.

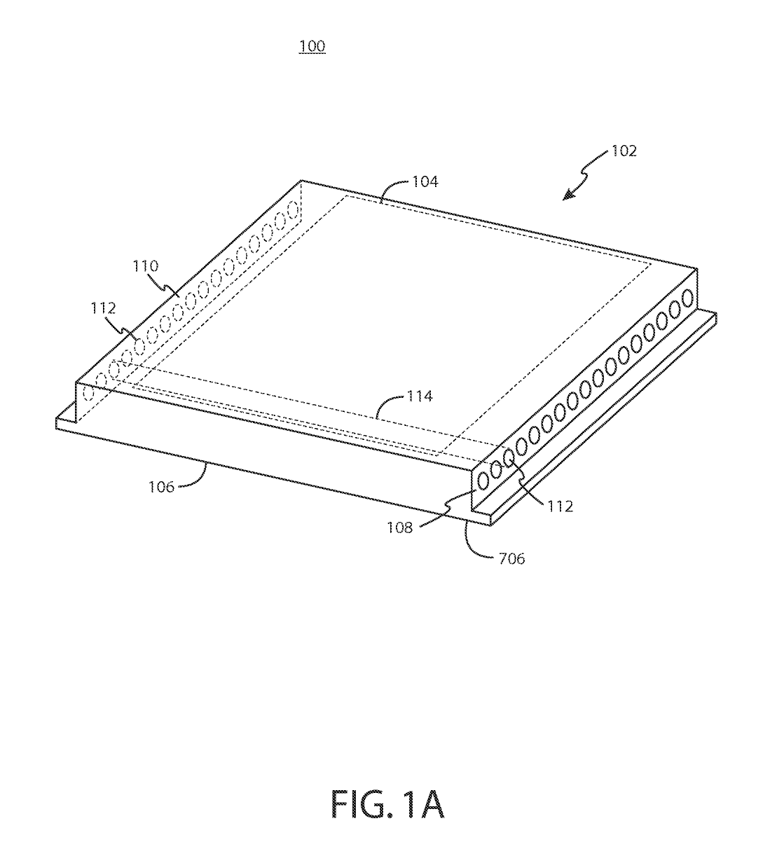

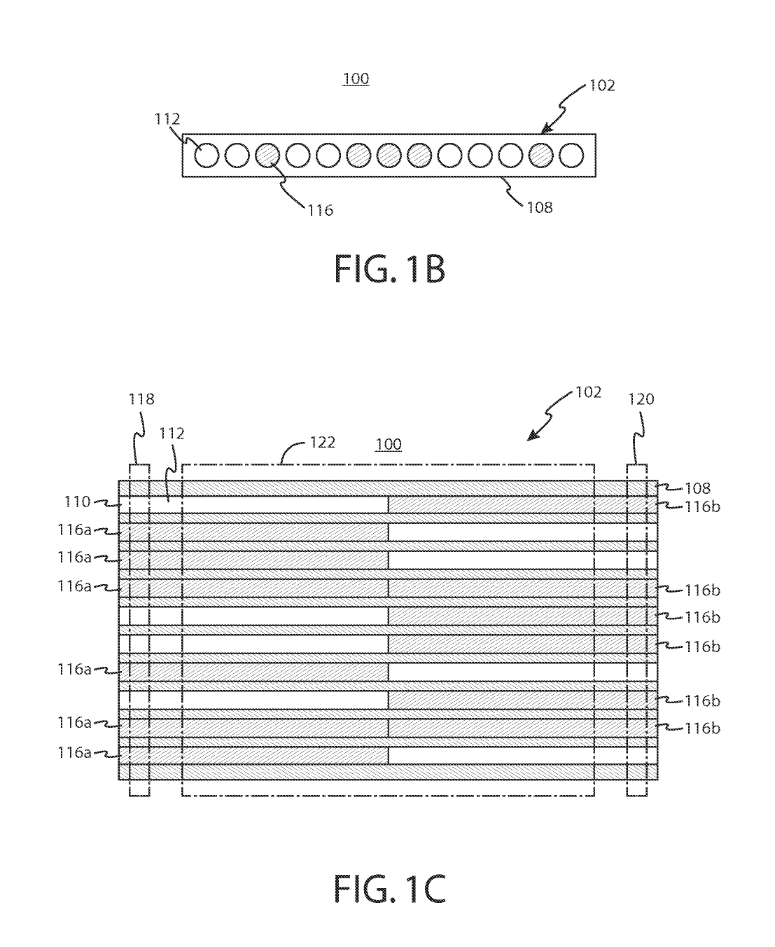

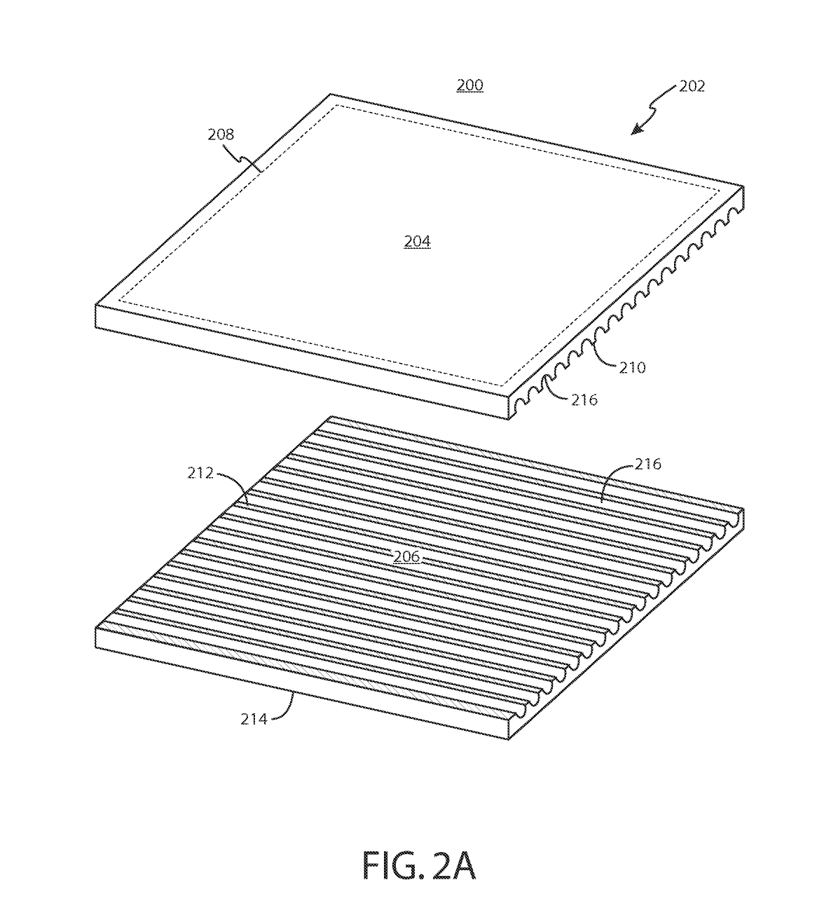

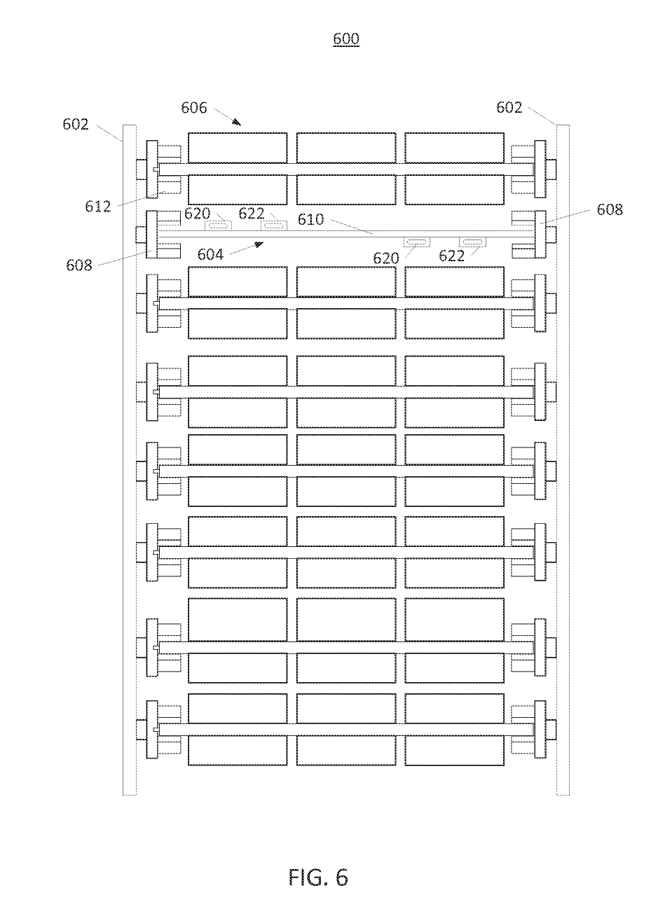

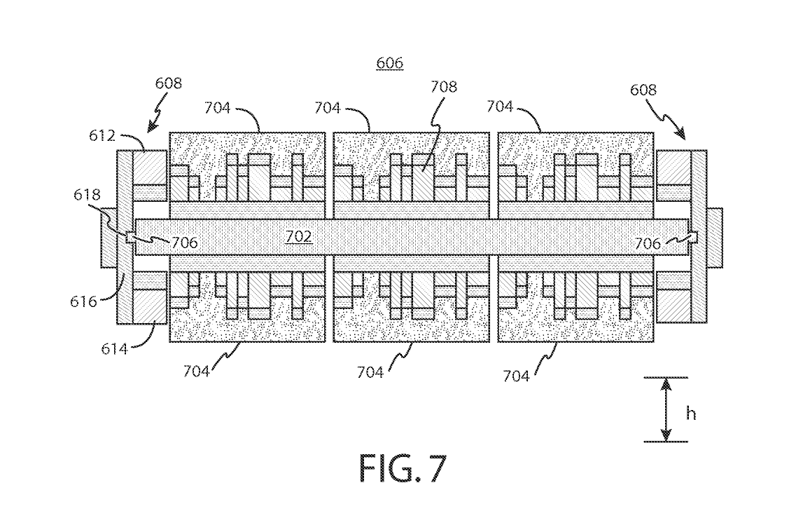

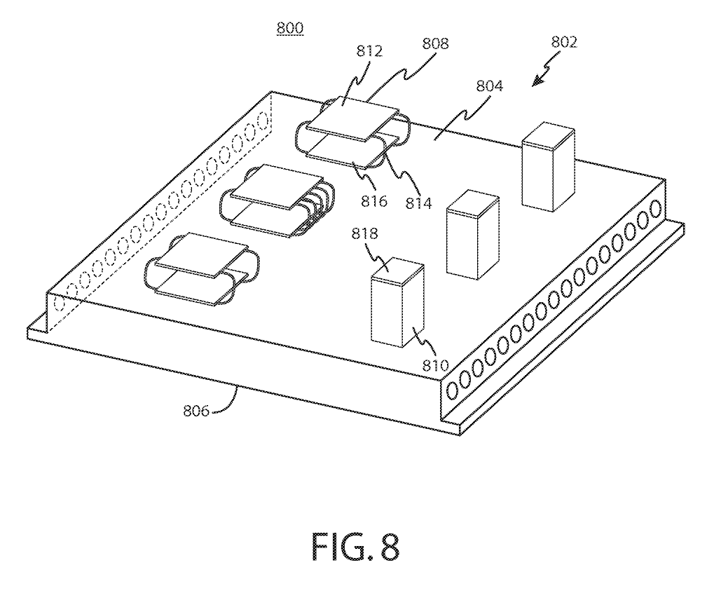

FIGS. 1A-1C show examples of a configurable heat transfer grid 100 in accordance with some embodiments. Configurable heat transfer grid 100, as well as the other configurable heat transfer grids discussed herein, may be used to provide cooling and/or support for computing components (e.g., Printed Circuit Board Assemblies (PCBAs), processing components, memory/storage components, power components, networking components, etc.). In some embodiments, a configurable heat transfer grid may be used to provide cooling to a module of a system, such as edge-coolable module 606 shown in FIGS. 6 and 7, and/or heat transfer grid 800 shown in FIG. 8. In some embodiments, a configurable heat transfer grid may be used with components, PCBAs, modules, and/or systems different from those discussed herein.

FIG. 1A shows a perspective view of an example of a configurable heat transfer grid 100 in accordance with some embodiments. Configurable heat transfer grid 100, as some or all of the heat transfer grids discussed herein, may be “self-contained” in that it may serve as a conduction cooling intermediary between components (and/or PCBAs including components) and cooling components (e.g., that may or may not be self-contained, such as cooling components that utilize cooling fluid flow). Configurable heat transfer grid 100 may include cooling frame 102 that defines cooling plane 104 (shown in outline) and cooling plane 106 (opposite cooling plane 104 and not shown, to avoid overcomplicating the disclosure), one or more of which may be configured to couple thermally with PCBAs, an example of which is shown in FIG. 7. In some embodiments, cooling frame 102 may be formed from a mechanically rigid and heat conductive material (e.g., aluminum) to facilitate heat transfer between heat transfer grid 100 and thermally coupled components and/or PCBAs. Cooling frame 102 may further include an outer end 108 and an outer end 110.

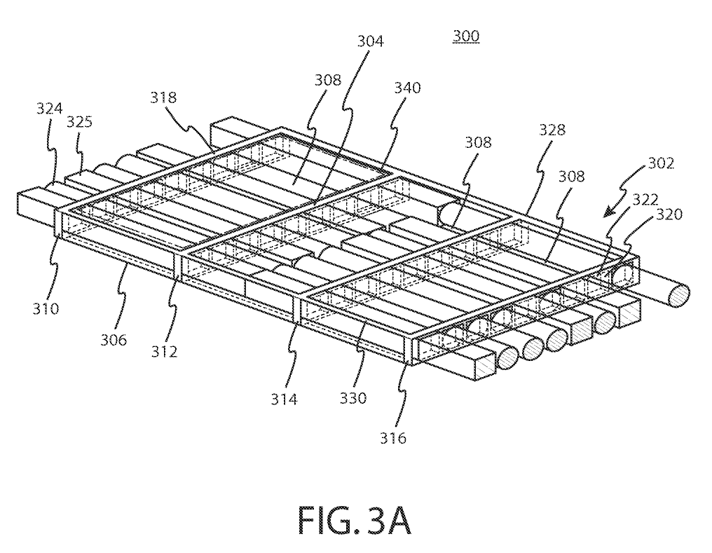

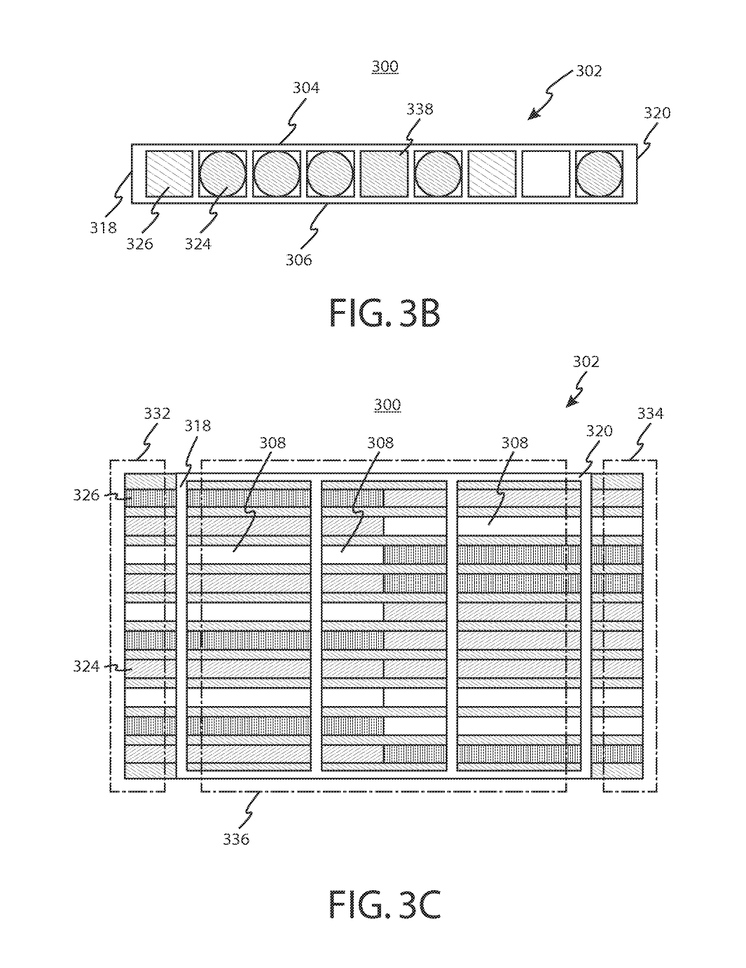

Cooling frame 102 may include and/or define a plurality of receptacles 114 that are each configured to receive one or more cooling elements. The cooling elements may be configured to promote more effective heat transfer between thermally coupled components and configurable heat transfer grid 100. In some embodiments, the one or more cooling elements may be heat pipes configured to facilitate heat transfer across the elongated length of the heat pipes. A “heat pipe,” as used herein, refers to a liquid-to-gas two phase cooling element. A heat pipe may include one or more cavities including a liquid in contact with a thermally conductive surface within the heat pipe (e.g., at and/or proximate to a component interface region of the heat transfer grid) that turns the liquid into a vapor. The vapor may then travel within the cavity to a cooling interface (e.g., at and/or proximate to an external heat exchange interface region of the heat transfer grid) and condense back into a liquid. One or more apertures 112 may be disposed between cooling plane 104 and cooling plane 106, through which a cooling element may be inserted into a receptacle 114. Although only a single receptacle 114 is shown in outline in FIG. 3A, to avoid overcomplicating the disclosure, configurable heat transfer grid 100 may include a plurality of apertures 112 that may define a plurality of receptacles 114.

FIG. 1B shows a side view and FIG. 1C shows a cross-sectional top view of exemplary configurable heat transfer grid 100 in accordance with some embodiments. With reference to FIGS. 1A and 1B, outer end 108 of cooling frame 102 may include apertures 112 between the cooling plane 104 and cooling plane 106 that each define a receptacle 114. Receptacles 114 may include an elongated shape that defines an elongated direction (e.g., between outer end 108 and outer end 110). In some embodiments, receptacles 114 collectively span a width of the cooling frame, the width being defined perpendicular to the elongated direction of receptacles 114.

Configurable heat transfer grid 100 may further include one or more cooling elements 116. Cooling elements 116 may include an elongated shape and/or may otherwise be formed to be received (e.g., via insertion and/or any other suitable technique) within receptacle 114, such as through apertures 112 at at least one of outer ends 108 and 110. Although apertures 112, receptacles 114, and cooling elements 116 are each shown as having a circular cross-section, other cross-sectional shapes (e.g., square, oval, flattened circular, etc.) may also be used for one or more of the apertures, receptacles, and/or cooling elements.

With reference to FIG. 1C, cooling elements 116a have been inserted into a portion of the receptacles from outer end 110, and cooling elements 116b have been inserted into a second portion of the receptacles from outer end 108. Some example cooling elements, such as heat pipes, may have a characteristic maximum heat transfer length (e.g., about 10 inches), beyond which the cooling elements are no longer capable of effective heat transfer. Here, cooling elements 116a and 116b may each be designed to be no longer than their maximum heat transfer length.

To support configurable heat transfer grids larger than the maximum heat transfer length of a cooling element (e.g., about 20 inches or 2 times the maximum heat transfer length in some embodiments), the arrangement of cooling elements may be bifurcated (e.g., or trifurcated, etc.) such that cooling elements 116a are configured to move heat toward outer end 110, and cooling elements 116b are configured to move heat toward opposite outer end 108. Here, each cooling element 116 may configured to carry heat for a distance that does not exceed the maximum heat transfer length, notwithstanding the larger (e.g., 2×) heat flow dimension of the configurable heat transfer grid. In some embodiments, such as where the applicable dimensions of a configurable heat transfer grid do not exceed the maximum heat transfer length of the cooling elements, each receptacle may receive a single cooling element (e.g., that extends to both of the outer ends of the configurable heat transfer grid). Furthermore, the apertures that provide access to the receptacles may be disposed on only a single outer end. As discussed in greater detail below, cooling elements may be disposed within one or more of receptacles 114 as may be necessary or desirable in view of the cooling requirements of the module.

In some embodiments, a heat flow dimension of one or more cooling elements may provide in-line heat exchange (e.g., along the elongated length of the cooling element and/or receptacle), for heat generating and heat dissipating components disposed along the heat flow dimension. For example, one or more processors, memories, etc., and one or more cooling blocks and/or cooling components that take heat away from the heat transfer grid, may be disposed along the heat flow dimension (e.g., in various orders, including staggered, interleaved, and/or intermixed heat generating and heat dissipating components).

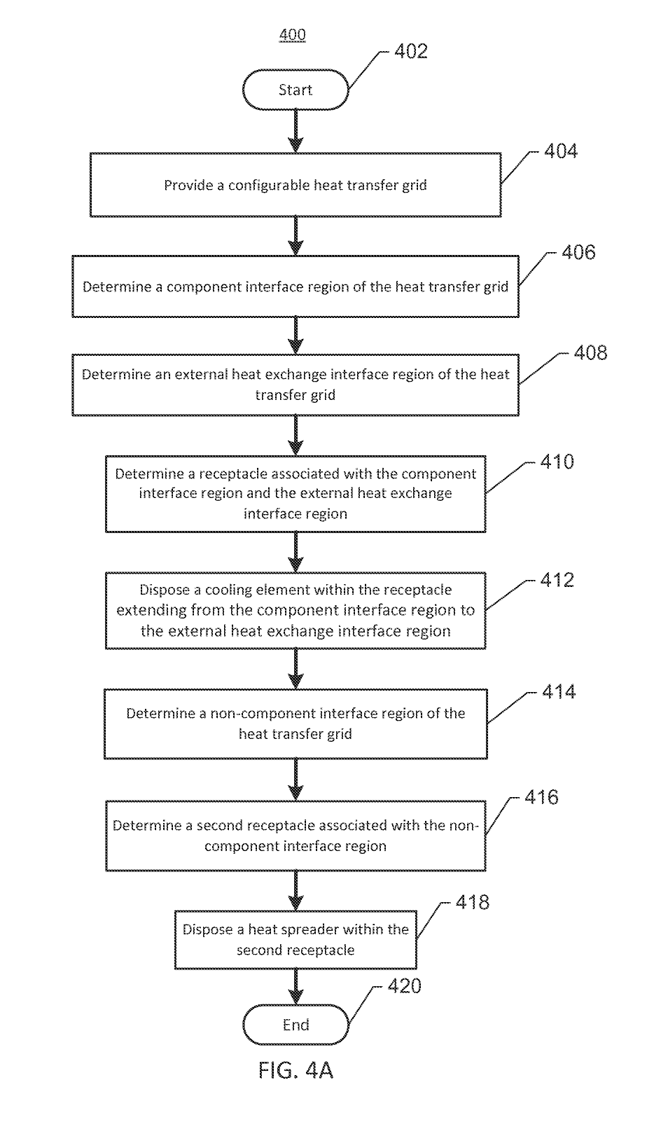

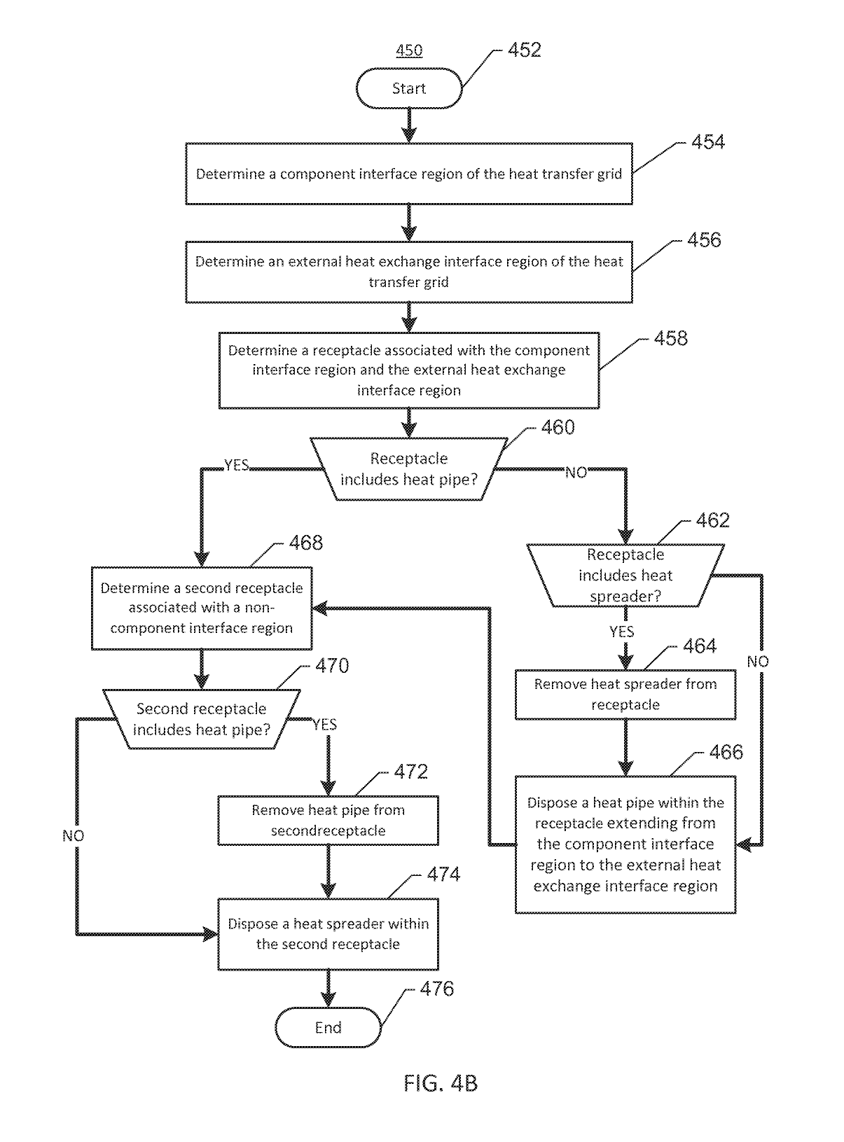

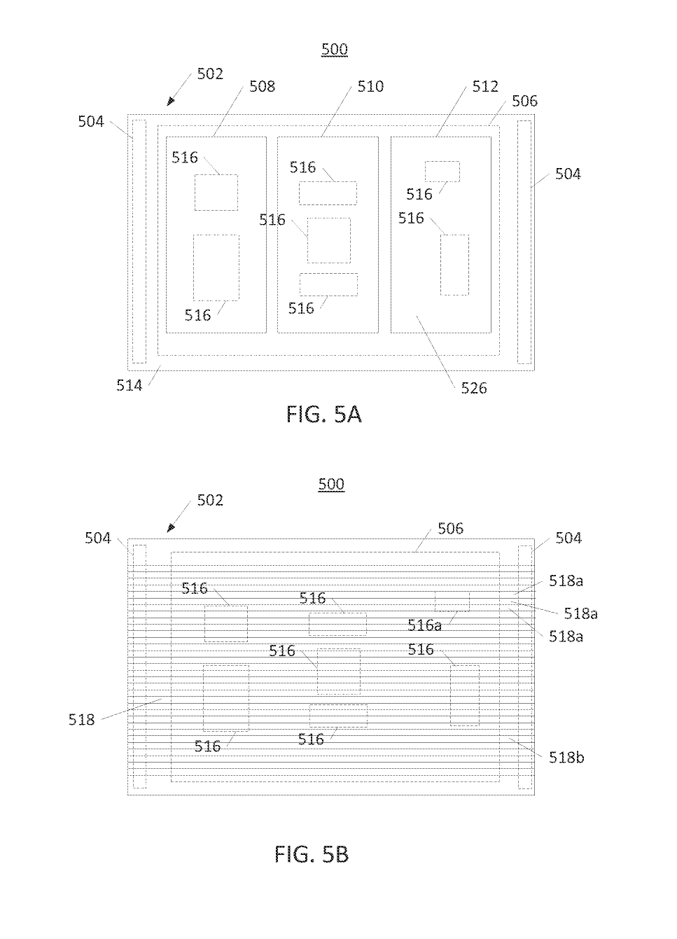

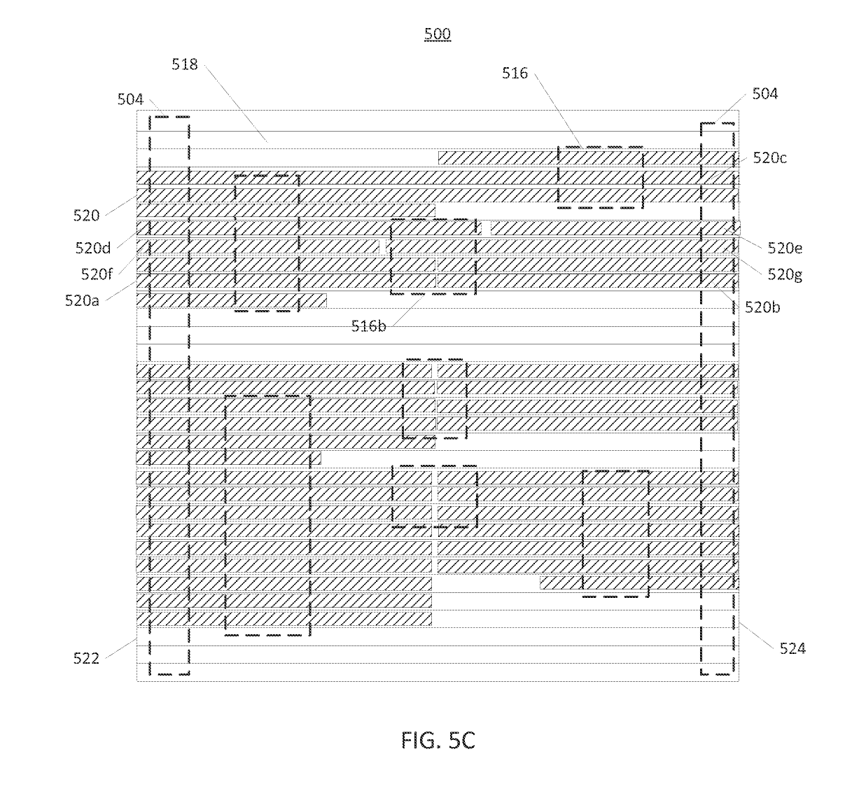

In some embodiments, a heat transfer grid may alternatively include a fixed arrangement of cooling elements optimized for a particular PCBA configuration, or a non-optimized arrangement for universal heat transfer coverage (e.g., cooling elements in each receptacle that are fixed during manufacturing). The latter technique, while providing universal coverage, may result in increased costs for cooling elements that may not be needed for a particular cooling application (e.g., as could be dictated by the arrangement, size, and/or location of components on a thermally coupled PCBA, among other things). As such, configurable heat transfer grid 100 may provide reduced costs by including receptacles that can removably receive cooling elements such that the cooling elements can be inserted into selected receptacles, but not all receptacles. Techniques for selecting receptacles in which to place one or more cooling elements are discussed below with reference to FIGS. 4-5C.

With reference to FIGS. 1C, 6, and 7, cooling frame 102 may further include cooling clamp engagement 706 disposed along outer ends 108 and 110, configured to engage a module guide 618 of a clamping mechanism 604. As discussed in further detail below, clamping mechanism 604 may include one or more cooling clamps 608 configured to simultaneously mechanically secure cooling frame 102 at and/or along external heat exchange interface regions 118 and 120 as well as to move heat at PCBA interface region 122 toward external heat exchange interface regions 118 and 120. In some embodiments, one or more cooling clamp engagements (e.g., corresponding with one or more module guides) may be disposed along outer ends of cooling frame 102 corresponding with the external heat exchange interface regions, such as outer ends 108 and 110 that respectively correspond with external heat exchange interface regions 120 and 118. While each of the heat transfer grids discussed herein may include clamp engagements, they are omitted from the exemplary heat transfer grids shown in FIGS. 1B-3C, to avoid unnecessarily overcomplicating the disclosure. In some embodiments, a configurable heat transfer grid may not include any clamp engagements.

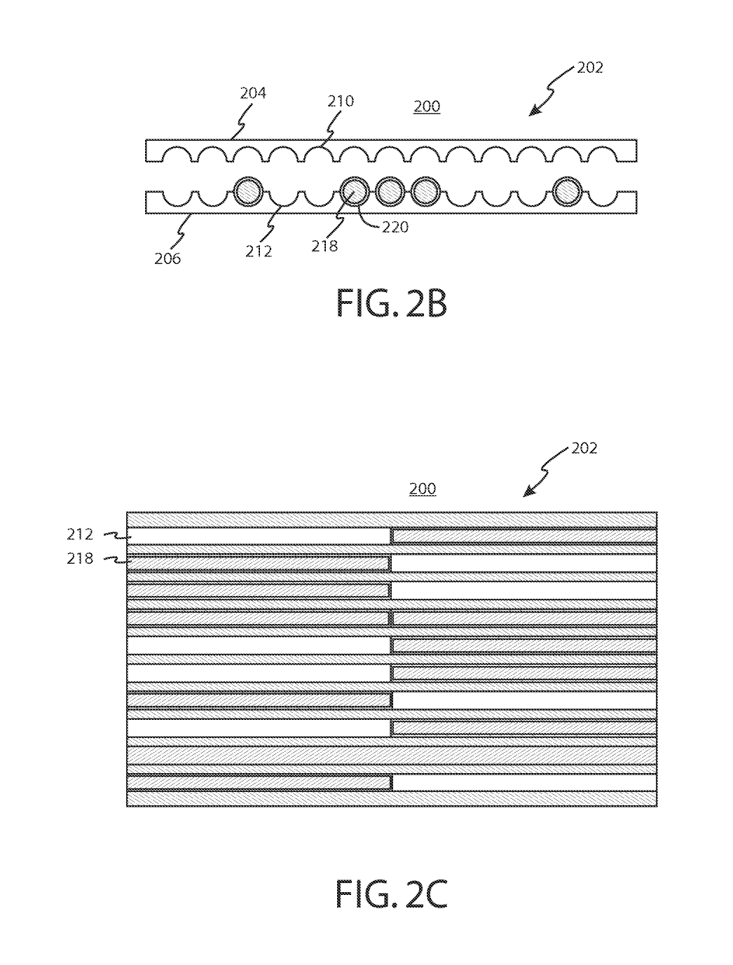

FIGS. 2A-2C show examples of a configurable heat transfer grid 200 in accordance with some embodiments. With reference to FIG. 2A, showing a perspective view of configurable heat transfer grid 200, heat transfer grid 200 may include a split cooling frame 202 including contoured component 204 and contoured component 206. Contoured component 204 may define a cooling plane 208 and a channel surface 210 opposite cooling plane 208. Contoured component 206 may define a channel surface 212 and a cooling plane 214 opposite channel surface 212. Channel surfaces 210 and 212 may each define a plurality of channels 216. Contoured components 204 and 206 may be configured to be removably placed together. Channels 216 in contoured components 204 and 206 may be configured such that when contoured components 204 and 206 are placed together, channels 216 of the combination of contoured components 204 and 206 form elongated receptacles (e.g., as shown by elongated receptacle 114 in FIG. 1A), each configured to receive one or more cooling elements.

In some embodiments, contoured components 204 and 206 may each be formed of a mechanically rigid and heat conductive material, such as aluminum. Contoured components 204 and 206 may be configured to be mechanically separable from and securable with each other, such as via one or more screws and/or any other suitable mechanical attachment.

FIG. 2B shows a side view, and FIG. 2C shows a cross-sectional top view, of exemplary configurable heat transfer grid 200, in accordance with some embodiments. Channel surfaces 210 and/or 212 of contoured components 204 and 206, respectively, may be configured to receive one or more cooling elements 218 when contoured component 204 is separated from contoured component 206. In that sense, the one or more cooling elements 218 can be disposed in one or more of the receptacles (e.g., formed by channel surfaces 210 and 212 when contoured components 204 and 206 are placed together) of configurable heat transfer grid 200. Configurable heat transfer grid 200 may be configured to include various arrangements of cooling elements 218 that can be changed subsequent to the separation of contoured component 204 from contoured component 206 of split cooling frame 202.

In some embodiments, split cooling frame 202 may define outer ends (e.g., as collectively defined by end portions of contoured components 204 and 206 when placed together) that include apertures (e.g., similar to apertures 112 at outer ends 108 and 110 shown in FIG. 1A). In some embodiments, some or all of the apertures may be removed because cooling elements can be inserted within receptacles via placement on channel surface 210 or 212 when split cooling frame 202 is opened (e.g., alternatively or in addition to insertion within a receptacle through an aperture), and then contoured components 204 and 206 may be joined to form the receptacles around the placed cooling elements. FIG. 2C shows an example arrangement of cooling elements 218 within heat transfer grid 200. The discussion above regarding configurations of cooling elements in large heat transfer grids (e.g., having a heat flow dimension that is longer than the maximum heat transfer length of cooling elements), may be applicable to heat transfer grid 200. For example, a receptacle of heat transfer grid 200 may removably include one or more cooling elements.

In some embodiments, one or more layers of thermal interface material (TIM) 220 may be disposed between a cooling element and the channel surface of the receptacle in which the cooling element is disposed. In some embodiments, TIM 220 may be disposed between each cooling element and an associated receptacle. TIM 220 may be configured to facilitate heat transfer between the receptacles of split cooling frame 202 and cooling elements 218. In some embodiments, TIM 220 may include graphene. Graphene refers to a single layer, 2-dimensional, crystalline allotrope of carbon that is strong, light, and an effective conductor of heat. In some embodiments, TIM 220 may additionally or alternatively include one or more other types of materials, including graphite-based and/or carbon-based materials, that also help facilitate heat conduction. In some embodiments, TIM 220 may alternatively or additionally include conformable and/or compressible thermally-conductive foams, sponges, pads, putties, gap-fillers, shims, and/or any other suitable forms of thermal interface materials. Configurable heat transfer grid 200, including split cooling frame 202, may be particularly well adapted for efficient, effective, and uniform placement of TIMs, because the opened cooling frame can allow the TIM to be disposed without risk of being scraped away or otherwise disturbed and/or displaced (e.g., as may occur during insertion of cooling elements through tightly fitting apertures and/or pre-formed channels).

FIGS. 3A-3C show examples of a configurable heat transfer grid 300, in accordance with some embodiments. With reference to FIG. 3A, showing a perspective view of configurable heat transfer grid 300, configurable heat transfer grid 300 may include cooling frame 302 that defines cooling side 304 and cooling side 306, one or more of which may be configured to couple thermally with components and/or PCBAs. At cooling sides 304 and 306, cooling frame 302 may define one or more cooling element access regions 308 at which cooling elements disposed within cooling frame 302 are exposed for thermal coupling with components and/or PCBAs. In that sense, two or more cooling elements may define a cooling plane at a cooling element access region, such as cooling plane 340. With reference to FIG. 3C, showing a cross-sectional top view of configurable heat transfer grid 300, cooling element access regions 308 may correspond with the PCBA interface region 336 of cooling frame 302. Cooling frame 302, configured to provide exposed cooling elements that define cooling planes, may also be referred to as an “open cooling frame.”

Cooling frame 302 may include and/or define a plurality of receptacles that are configured to receive one or more cooling elements. Rather than being formed by channels (e.g., including channel surfaces that surround cooling elements along their elongated length), the receptacles of cooling frame 302 may be defined by one or more element guides 310, 312, 314, and/or 316 of cooling frame 302. Element guides 310 and 316 may be outer element guides, respectively defining outer end 318 and outer end 320 of cooling frame 302. One or more apertures 322, through which a cooling element may be inserted, may be disposed between cooling sides 304 and 306, to define one or more receptacles for cooling elements. For example, in some embodiments, each of the element guides may include a corresponding number of apertures 322 that are collinear such that they collectively guide cooling elements within receptacles. In some embodiments, cooling frame 302 may include one or more inner element guides, such as element guides 312 and 314. Element guides 312 and 314 may also include one or more apertures (e.g., each corresponding to an aperture in one or more of the outer element guides), such that the outer element guides and inner element guides collectively define the receptacles of cooling frame 302 via their apertures 322. Inner element guides, when used, may define a plurality of cooling element access regions 308 that are separated by the inner element guides.

In some embodiments, each cooling element access region 308 may be coupled thermally with a different PCBA. At a cooling element access region 308, the components of the thermally coupled PCBA may be disposed in thermal contact with the exposed cooling elements. The PCBAs may be mounted to heat transfer grid 300 via mechanical attachment to cooling frame 302. For example, one or more PCBAs may be secured to cooling side 304 of cooling frame 302 (e.g., via screws and/or any other suitable mechanisms) at one or more suitable attachment points, such as at element guides, and/or at guide supports of cooling frame 302 that connect the element guides (e.g., guide supports 328 and/or 330 that connect element guides 310, 312, 314, and/or 316 with each other on opposite ends). Similarly, one or more PCBAs may be secured to cooling side 306 (e.g., opposite to side 304) of cooling frame 302, such as at opposite sides of the element guides and/or guide supports of cooling frame 302. In that sense, cooling frame 302, defining three cooling element access regions, may provide cooling for up to six PCBAs: up to three PCBAs disposed proximate to cooling side 304, and up to three PCBAs disposed proximate to cooling side 306.

In some embodiments, cooling frame 302 may include one or more adjustable element guides. For example, inner element guides 312 and/or 314 may be configured to connect with guide supports 328 and 330 at variable locations along guide supports 328 and 330 between outer element guides 310 and 316. Adjustable element guides may allow cooling frame 302 to adapt to modules and/or components of different sizes and/or dimensions, by providing variably sized cooling element access regions and PCBA mounting locations.

With reference to FIGS. 3A and 3B (showing a side view of heat transfer grid 300), apertures 322 (as well as one or more apertures of the other heat transfer grids discussed herein) may be configured to receive cooling elements of differing types and/or functions. In some embodiments, the cooling elements may be inserted within receptacles through the apertures at one or more of outer ends 318 and 320. In some embodiments, cooling frame 302 may alternatively or additionally be a split open cooling frame, to allow cooling element placement when half portion element guides are separated from each other.

Cooling frame 300 (e.g., as well as the other cooling frames discussed herein) may include cooling elements comprising one or more heat pipes 324 and/or one or more heat spreaders 326. A heat spreader 326 may be configured to disperse heat received from PCBAs and/or components, such as to nearby regions, receptacles, and/or cooling elements. In some embodiments, a heat spreader 326 may be inserted into some or all of the receptacles of cooling frame 302 that do not include a heat pipe 324. In that sense, heat spreader 326 may include an elongated shape substantially corresponding with the shape of heat pipes 324 and/or apertures 322.

Heat spreaders 326 may provide for the dispersal of heat from regions that do not include a heat pipe, to an adjacent and/or proximate heat pipe, thereby allowing heat from such regions to be carried away via the heat pipe. In some embodiments, heat spreaders 326 may further be configured to provide structural support. For example, some or all of the weight of a PCBA and/or module may be supported by heat spreaders 326 and/or heat pipes 324 at the one or more cooling element access regions 308. In some embodiments, heat spreaders 326 may be formed of a relatively low cost, structurally strong, and heat conductive material (e.g., aluminum).

To support more efficient heat transfer between the cooling elements and PCBAs, the cooling elements of cooling frame 300 may include cross sections with flattened portions, such that the cooling elements collectively form planar and/or substantially planar heat transfer surfaces at cooling element access regions 308. As shown in FIG. 3B, heat spreaders 326 may include a rectangular cross section that is form-fitted to rectangular apertures 322. Heat pipes may include a flattened circular cross section, flattened along portions corresponding with cooling sides 304 and 306. In some embodiments, one or more heat pipes may include a rectangular cross section and/or be form-fitted to apertures 322 (e.g., apertures having circular, rectangular and/or flattened circular shape, and/or any other shape). For example, heat pipe 338 includes a rectangular cross section form-fitted to an aperture.

With reference to FIG. 3C, cooling elements, including heat pipes 324 and/or heat spreaders 326, may be configured to extend beyond the outer ends 318 and 320 of cooling frame 302. External heat exchange interface regions 332 and 334 may be defined by the protruding portions of the cooling elements, such that a clamping mechanism 604 (discussed in greater detail below) may simultaneously secure and provide cooling to heat transfer grid 300 via the protruding portions of the cooling elements at external heat exchange interface regions 332 and 334. While heat exchange interface regions 332 and 334 (e.g., as well as other external heat exchange interface regions herein) are shown as being defined at the edges of the cooling planes of a heat transfer grid (e.g., at, along, and/or near an outer edge), in various other embodiments these heat exchange interface regions may be defined by other regions of the cooling plane. In that sense, regardless of the location of component interface regions and/or external heat exchange interface regions, a cooling element may be positioned within a receptacle as suitable to extend from a component interface region to an external heat exchange interface region.

FIG. 4A shows an example of a method 400 for configuring a configurable heat transfer grid, in accordance with some embodiments. Method 400 may begin at 402 and proceed to 404, where a configurable heat transfer grid may be provided. The configurable heat transfer grid may include the example configurable heat transfer grids disclosed herein, among other things. For example, the configurable heat transfer grid may define a plurality of receptacles, each receptacle configured to (e.g., removably) receive one or more cooling elements.

In some embodiments, providing the configurable heat transfer grid may include manufacturing the cooling frame. For example, one or more PCBA interface regions and external heat exchange interface regions of the cooling frame may be determined. Next, a plurality of receptacles of the cooling frame may be defined and/or formed, such that the receptacles extend from a PCBA interface region to an external heat exchange interface region.

FIGS. 5A-5C show schematic top views of an example of a configurable heat transfer grid 500, in accordance with some embodiments. With reference to FIGS. 5A and 5B, heat transfer grid 500 may include cooling frame 502, defining external heat exchange interface regions 504 and PCBA interface region 506 on cooling side 514. Receptacles 518 may be arranged in parallel rows, and extend from at least PCBA interface region 506, to one or more of external heat exchange interface regions 504. In some embodiments, the opposite cooling side of cooling frame 502 may additionally or alternatively define one or more component interface regions and/or PCBA interface regions. The component interface regions and/or PCBA interface regions at opposite cooling sides may correspond with respect to each other, such that receptacles 518 extend from the PCBA interface regions to external heat exchange interface regions on each side. In some embodiments, PCBA interface regions and/or external heat exchange interface regions may be in different locations on the opposite cooling sides. The configurable heat transfer grid may include more than one set of receptacles, such as two layers of receptacles (e.g., rather than the single receptacle layers shown in FIGS. 1A-3C). Here, each layer of receptacles may be defined independently based on the cooling requirements at the proximate cooling side. In another example, such as when a heat transfer grid includes a single layer of receptacles for two cooling sides, the receptacles and/or cooling elements may be disposed as discussed in method 400 for a single cooling side, albeit with similar consideration given simultaneously to the interface regions on the two cooling sides.

At 406, one or more component interface regions of the heat transfer grid may be determined. A “component interface region”, as used herein, refers to a region of a surface of the heat transfer grid that is configured to couple thermally (e.g., via direct contact and/or through a heat exchanger and/or other thermal interface) with a heat generating component of an attached PCBA. In some embodiments, the highest-flux heat generating components of the PCBA (e.g., processing components) may be associated with component interface regions, while lower-flux heat generating components (e.g., memory/storage components, networking components, etc.) may be associated with non-component interface regions. In that sense, the component interface regions of the heat transfer grid may be defined as the regions that receive the highest heat flux from heat generating components. In order to avoid unnecessary costs associated with placement of cooling elements (e.g., heat pipes) within receptacles in locations where cooling elements are not needed, the configurable heat transfer grid may be configured and/or reconfigured (e.g., post-manufacturing) to optimize placement of cooling elements for effective heat removal at the component interface regions, based on specific configurations of attached heat generating components.

With reference to FIG. 5A, one or more PCBAs 508, 510, and 512 may be disposed within PCBA interface region 506. Each of PCBAs 508, 510, and 512 may include one or more components (e.g., computing components associated with processing, memory/storage, networking, power conversion, etc.) that are disposed to face cooling side 514. Within PCBA interface region 506, cooling frame 502 may define a plurality of component interface regions 516 that correspond with the locations of the one or more components of PCBAs 508, 510 and 512. As discussed above, in some embodiments, heat transfer grid 500 may include interface regions on the cooling side opposite to cooling side 514. The component interface regions on each of the opposing cooling sides may be configured independently, as may be necessary to accommodate different PCBA structures and dimensions. Accordingly, component interface regions on opposite cooling sides may not necessarily be mirrored or correspond with each other.

In some embodiments, determining the one or more component interface regions of the heat transfer grid may include: securing a PCBA to the heat transfer grid, and/or determining the component interface region as a region of the heat transfer grid that is in direct and/or nearest thermal contact with a component of the PCBA, when the PCBA is secured to the heat transfer grid.

At 408, an external heat exchange interface region of the heat transfer grid may be determined. An “external heat exchange interface region”, as used herein, refers to a region of a surface of the heat transfer grid that is configured to couple thermally (e.g., via direct contact and/or through a heat exchanger and/or other thermal interface) with a cooling component that removes heat from the heat transfer grid. For example, heat transfer grid 500 may include external heat exchange interface regions 504 adjacent to and parallel to one or more outer ends of heat transfer grid 500. In other examples, an external heat exchange interface region may be defined in areas of heat transfer grid 500 that are farther from the outer ends.

Next, a cooling element may be disposed within a receptacle extending from the component interface region to the external heat exchange interface region. As discussed above, one or more external heat exchange interface regions may be located at and/or near the edges of a cooling plane, such that heat can be carried to the edges of the cooling plane where cooling components may be coupled thermally with the cooling plane. However, in some embodiments, areas of the cooling plane that are different from and/or farther from an edge may alternatively or additionally include an external heat exchange interface region.

At 410, a receptacle associated with the component interface region and the external heat exchange interface region may be determined. For example, receptacles 518a may each be associated with component interface region 516 and an external heat exchange interface region 504, because receptacles 518a extend from component interface region 516 to an external heat exchange interface region 504. In contrast, receptacle 518b may be determined to not be associated with a component interface region at any portion of its elongated length, because receptacle 518b fails to extend through a component interface region.

At 412, a cooling element may be disposed within the receptacle extending from the component interface region to the external heat exchange interface region. With reference to FIG. 5C, a cooling element 520 (e.g., a heat pipe) may be disposed within each receptacle 518 associated with a component interface region 516. In another example, cooling element 520a may be disposed within a receptacle 518 extending from component interface region 516b to an external heat exchange interface region 504. In some embodiments, each cooling element 520 (e.g., a heat pipe) may be disposed within receptacles 518 and may be of a length and/or location such that the cooling element extends from at least one component interface region to at least one external heat exchange interface region.

As discussed above, each cooling element 520 may include a maximum heat transfer length that defines a maximum length of effective heat transfer. Receptacles that are longer than the maximum heat transfer length may include a plurality of cooling elements. For example, cooling elements 520a and 520b are disposed within the same receptacle, such that each does not fully extend to and/or beyond outer end 522 and outer end 524. Cooling elements 520a and 520b may each extend across approximately half of the distance from outer end 522 to outer end 524. In some embodiments, cooling elements disposed within adjacent and/or proximate receptacles may be of staggered lengths (e.g., to avoid creating one or more areas of reduced cooling effectiveness, such as could occur along the midpoint between the outer ends of the heat transfer grid, where half-length cooling elements within each receptacle would meet). For example, cooling element 520d may extend beyond the midpoint, and cooling element 520e, within the same receptacle, may correspondingly end short of the midpoint. In an adjacent and/or proximate receptacle, cooling element 520f may end short of the midpoint, while cooling element 520g, within the same receptacle, may correspondingly extend beyond the midpoint.

In another example (e.g., where the width of the entire receptacle does not exceed the maximum heat transfer length of a cooling element), the receptacle may include a single cooling element, such as cooling element 520c. Cooling element 520c may extend at least from outer end 522 to outer end 524, and/or may extend beyond one or more of outer ends 522 and 524 (e.g., for an open cooling frame).

A cooling element may be disposed within the configurable heat transfer grid using any of the techniques disclosed herein. For a heat transfer grid where cooling elements may be inserted via apertures at the outer ends (e.g., heat transfer grid 100 and/or heat transfer grid 300), disposing the cooling element within a receptacle associated with the component interface region may include inserting the cooling element into the receptacle via an aperture at an outer end of the cooling frame. In some embodiments, a TIM may be disposed between the cooling element and the receptacle. For example, the TIM may be disposed on the cooling element prior to insertion. In another example, the TIM may be disposed within the receptacle prior to insertion of the cooling element.

For a split heat transfer grid that is separable (e.g., heat transfer grid 200), disposing the cooling element within a receptacle associated with the component interface region may include separating a first contoured component of the cooling frame from a second contoured component of the cooling frame. As discussed above, the first contoured component and the second contoured component may each include a plurality of channels that are configured such that when the first contoured component and the second contoured component are placed together, the channels form the plurality of receptacles. Next, the cooling element may be disposed within a channel of the first contoured component or the second contoured component. Subsequent to disposing the cooling element within the channel (e.g., as well as any other cooling elements such as heat pipes and/or heat spreaders), the first contoured component and the second contoured component may be joined to form the receptacles within which the cooling elements are disposed. In some embodiments, prior to joining the first contoured component with the second contoured component, a TIM may be disposed between the cooling element and one or more channel surfaces of the contoured components. For example, the TIM may be disposed onto the exterior elongated surface(s) of the cooling element, and/or the channel surface of the first contoured component and/or second contoured component.

In some embodiments, a configurable heat transfer grid may be configured to receive cooling elements using one or more of these techniques. For example, the configurable heat transfer grid may include a split cooling frame that also includes apertures at one or more outer ends for receiving cooling elements via insertion (e.g., after the separable contoured components of the split cooling frame have been joined, and without requiring another separation of the contoured components).

At 414, one or more non-component interface regions of the heat transfer grid may be determined. With reference to FIG. 5A, for example, non-component interface region 526 may be defined as a region within PCBA interface region 506 that is outside of component interface regions 516.

At 416, a second receptacle associated with the one or more non-component interface regions may be determined. For example, and with reference to FIG. 5B, receptacle 518b may be determined to be associated with a non-component interface region, and unassociated with a component interface region, because receptacle 518b does not extend across any component interface region 516. In some embodiments, each receptacle other than those determined to be associated with a component interface region (at 410), may be determined to be associated with a non-component interface region.

At 418, a heat spreader may be disposed within the second receptacle associated with the non-component interface region. Heat spreaders may be inserted into the receptacles of any of the configurable heat transfer grids discussed herein. For heat transfer grids that include open cooling frames, heat spreaders may be particularly beneficial, by providing for the movement of heat from non-component interface regions to heat pipes, for removal at one or more external heat exchange interface regions. In some embodiments of heat transfer grids that include non-open cooling frames, such as those that include channel walls that fully define the receptacles, heat spreaders may be omitted, as a similar heat spreading effect may be provided by the cooling frame structure itself. However, in some other embodiments of heat transfer grids that include non-open cooling frames, one or more heat spreaders may be included in receptacles of cooling frames. Method 400 may then proceed to 420 and end.

FIG. 4B shows an example of a method 450 for reconfiguring a configurable heat transfer grid, in accordance with some embodiments. Method 450 may be performed subsequent to method 400, such as to reconfigure a heat transfer grid for a different PCBA and/or component(s).

Method 450 may begin at 452 and proceed to 454, where a component interface region of the heat transfer grid may be determined. For example, the discussion at 406 of method 400, may be applicable at 452. However, in some examples, a different PCBA and/or component(s) may be used, or the same PCBA may be mounted in a different way, resulting in a change in one or more component interface regions, relative to the previous configuration.

At 456, an external heat exchange interface region of the heat transfer grid may be determined. In some embodiments, the configuration of external heat exchange interface regions may not change when the configurations of one or more component interface regions are changed, e.g. via changes to configurations of PCBAs and/or other heat generating components. For example, different PCBAs and/or components may be mounted to the heat transfer grid, while the external heat exchange interface regions that interface with cooling components for heat removal and/or structural support, may remain the same. However, in some embodiments external heat exchange interface regions may also change.

At 458, a receptacle associated with the component interface region and the external heat exchange interface region may be determined. The discussion at 410 may be applicable at 458.

At 460, a determination may be made as to whether or not the receptacle includes a heat pipe extending from the component interface region to the external heat exchange interface region. In response to determining that the receptacle fails to include a heat pipe, method 450 may proceed to 462, where a determination may be made as to whether or not the receptacle includes a heat spreader extending from the component interface region to the external heat exchange interface region.

In response to determining that the receptacle does not include a heat spreader extending from the component interface region to the external heat exchange interface region (e.g., the receptacle is empty, or partially empty, in the region of interest), method 450 may proceed to 466, where a heat pipe may be disposed within the receptacle extending from the component interface region to the external heat exchange interface region. In response to determining that the receptacle does include a heat spreader extending from the component interface region to the external heat exchange interface region (e.g., the receptacle is not empty or partially empty in the region of interest), method 450 may proceed to 464, where the heat spreader may be removed from the receptacle. The method may then proceed to 466, where a heat pipe may be disposed within the receptacle extending from the component interface region to the external heat exchange interface region (e.g., in place of the heat spreader).

Method 450 may then proceed to 468. Similarly, returning to 460, in response to determining that the receptacle does include a heat pipe extending from the component interface region to the external heat exchange interface region, method 450 may proceed to 468, where a second receptacle associated with a non-component interface region may be determined. The discussion at 414 and 416 of method 400 may be applicable at 468. For example, the non-component interface region may be determined as a region that is outside of the component interface regions.

At 470, a determination may be made as to whether or not the second receptacle includes a heat pipe. In response to determining that the second receptacle does include a heat pipe, method 400 may proceed to 472, where the heat pipe may be removed from the second receptacle. For example, heat pipes within receptacles that are not associated with a component interface region (or associated with a non-component interface region) may be removed during a reconfiguration, for the purpose of avoiding unnecessary costs. Furthermore, a heat pipe that is removed from a first receptacle, may be re-used by disposing the same heat pipe within a second receptacle (e.g., at 466).

At 474, a heat spreader may be disposed within the second receptacle. The discussion at 418 of method 400 may be applicable at 474. Returning to 470, in response to determining that the second receptacle fails to include a heat pipe, method 450 may also proceed to 474. Alternatively, rather than disposing a heat spreader within the second receptacle, the second receptacle may be left empty (e.g., for non-open cooling frames). Method 450 may then proceed to 476 and end.

In some embodiments, a cooling performance test may be used during configuration and/or reconfiguration of a configurable heat transfer grid, to help optimize the configuration of cooling elements. For example, heat pipes and/or heat spreaders may be added, relocated, and/or removed as needed, based on the results of the test. The test may be repeated for the new configuration. In some embodiments, the test may include determining whether or not removing a cooling element from a receptacle would cause the cooling performance of the heat transfer grid to fall below the minimum acceptable level for a specific configuration of PCBAs and/or components attached to the heat transfer grid. For example, an initial configuration of a configurable heat transfer grid may be created by inserting a heat pipe into every receptacle. In another example, an initial configuration may be created by inserting a heat pipe into every receptacle that is associated with a component interface region, and/or any nearby (e.g., adjacent) receptacles. In response to determining that removing a specific cooling element would not cause cooling performance to fall below the minimum acceptable level, that cooling element may be removed from the receptacle. In another example, the test may include determining whether or not a specific cooling element should be inserted into a specific receptacle, in order to provide sufficient cooling for one or more PCBAs and/or components. For example, heat pipes may initially be inserted into only a subset of the complete set of receptacles that are associated with component interface regions (e.g., only the receptacles that are running across more centralized portions of a component interface region). In response to determining that a specific cooling element should be inserted into a specific receptacle, in order to increase cooling performance to the minimum acceptable level, a cooling element may be disposed within the receptacle. In some embodiments, an apparatus may be configured to perform the test via a simulation program that is configured to model the heat transfer characteristics of the heat transfer grid, for various PCBA and/or component configurations, and various configurations of cooling elements. The results of the computer-implemented simulation may then be used to configure and/or reconfigure one or more heat transfer grids.

FIG. 6 shows a front view of an example of a system 600, in accordance with some embodiments. While the configurable heat transfer grids discussed herein may be used in virtually any system, system 600 may be particularly well adapted for use with configurable heat transfer grids. System 600 may include a chassis 602, a plurality of clamping mechanisms 604, and a plurality of edge-coolable modules 606. Each clamping mechanism 604 may include one or more cooling clamps 608, such that each clamping mechanism 604 is capable of removably securing an edge-coolable module 606. In some embodiments, an edge-coolable module 606 may include a configurable heat transfer grid.

Cooling clamps 608 of a clamping mechanism 604 may be attached to each other via frame 610 of the clamping mechanism 604. The one or more cooling clamps 608 of a clamping mechanism 604 may be configured to removably secure an edge-coolable module 606 to chassis 602 via clamping mechanism 604. When edge-coolable module 606 is secured by cooling clamp 608 (e.g., via a cooling component 612, such as a cooling rail), cooling clamp 608 may be further configured to provide (e.g., conduction) cooling to edge-coolable module 606 and/or its components. For example, the locations of clamping mechanisms 604 along chassis 602 may be adjustable in order to accommodate edge-coolable modules of various dimensions. In another example, clamping mechanism 604 may additionally or alternatively be configured to provide networking and/or power to edge-coolable module 606, such via power connectors 620 and/or network connectors 622.

FIG. 7 shows a cross-sectional front view of an example of an edge-coolable module 606 in accordance with some embodiments. Edge-coolable module 606 may include configurable heat transfer grid 702 and one or more PCBAs 704 that may be coupled thermally with configurable heat transfer grid 702. In some embodiments, PCBAs 704 may be secured mechanically to configurable heat transfer grid 702, such as via screws, adhesive, magnetic force, and/or any other suitable technique to help promote thermal conduction between PCBAs 704 and heat transfer grid 702.

In some embodiments, edge-coolable module 606 may be removably inserted into one or more (e.g., any) clamping mechanisms 604 of system 600. In embodiments that facilitate slidable insertion of edge-coolable module 606 (e.g., from an open front portion of chassis 602 of system 600), configurable heat transfer grid 702 may include cooling clamp engagement 706 along one or more outer (e.g., side) end portions of configurable heat transfer grid 702. FIG. 7 also shows two cooling clamps 608 of a clamping mechanism 604. Cooling clamp 608 may include cooling components 612 and 614, clamp control element 616, and module guide 618. Clamp control element 616 may be configured to control a distance between cooling component 612 and cooling component 614, to open and close cooling clamp 608 against external heat exchange interface regions of configurable heat transfer grid 702. For example, edge-coolable module 606 may be slidably inserted into a module receiving area of clamping mechanism 604, by engaging cooling clamp engagement 706 of heat transfer grid 702 with module guide 618 of clamping mechanism 604, when cooling clamp 608 is opened. Cooling clamp 608 may then be closed to secure edge-coolable module 606 (e.g., to system 600) and/or to provide cooling to edge-coolable module 606, among other things. For example, heat generated by PCBAs 704 may be transferred to cooling components 612 and 614 of clamping mechanism 604 via configurable heat transfer grid 702.

In some embodiments, configurable heat transfer grid 702 and/or edge-coolable module 606 may include one or more thermal keys 708. Thermal key 708 may be disposed between a cooling plane of a heat transfer grid and a PCBA. In some embodiments, thermal key 708 may a one-piece component formed of heat conductive material, such as aluminum, and may provide a uniform planar surface for PCBA 704 to couple thermally with heat transfer grid 702. For example, PCBA 704 may include various components having different heights (e.g., along dimension h) relative to the PCB surface (component mounting plane) of PCBA 704. Without thermal key 708, the tallest component(s) of PCBA 704 may contact the cooling plane of heat transfer grid 702, while the shorter components may not, resulting in insufficient cooling of the shorter components.

Thermal key 708 may include one or more key interface regions. A key interface region of thermal key 708 may include a height that substantially correlates inversely with the height of an associated component when thermal key 708 is brought in contact with PCBA 704, such that PCBA 704 receives plane-to-plane or substantially plane-to-plane contact coupling with heat transfer grid 702 (e.g., the planar side of thermal key 708 defines the first plane, and the cooling plane of heat transfer grid 702 defines the second plane), regardless of the size, height, and/or location of components. In that sense, heat transfer grid 702 may include one or more thermal keys 708 in order to achieve surface-to-surface cooling with PCBAs having virtually any configuration of components. In some embodiments, TIM may be disposed between heat transfer grid 702 and thermal key 708, to further facilitate heat transfer.

In some embodiments, structures that allow components of a PCBA (e.g., having differing heights relative to the surface of the board) to make thermal contact with a cooling plane of a heat transfer grid, may be integrated with the heat transfer grid. FIG. 8 shows an example heat transfer grid 800 in accordance with some embodiments. Heat transfer grid 800 may include cooling frame 802 that defines cooling plane 804 and cooling plane 806. On the surface of cooling plane 804, one or more thermal bridges 808 and/or one or more thermal risers 810 may be disposed, attached mechanically, or incorporated with the cooling frame 802 (e.g., in a one-piece casting). Although not shown, one or more thermal bridges 808 and/or one or more thermal risers 810 may also be disposed on cooling plane 806.

Thermal bridge 808 may be configured to provide an interface for the transfer of heat from higher-flux heat generating components on the PCBA (e.g., processors) to heat transfer grid 800. In that sense, a thermal bridge 808 may be disposed on cooling plane 804 at component interface regions, such as processor component interface regions. Thermal bridge 808 may include PCBA interface 812, heat pipes 814, and grid interface 816. PCBA interface 812 may be a sheet of thermally conductive material (e.g., aluminum) that forms a contact and/or attachment interface with one or more components on the PCBA. Grid interface 816 may similarly be a sheet of thermally conductive material that forms a contact and/or attachment interface with cooling plane 804. One or more curved heat pipes 814 may be disposed between PCBA interface 812 and grid interface 816, to provide heat transfer from PCBA interface 812 to grid interface 816. In some embodiments, such as when a higher-flux heat generating component on the PCBA is of a height such as to be capable of contacting cooling plane 804 directly, a thermal bridge 808 may not be used for that heat generating component.

Thermal riser 810 may be configured to provide an interface for lower-flux heat generating components (e.g., power conversion components, memory/storage components, networking components, other PCBA components, etc.). Thermal riser 810 may be formed of a heat conductive material. The height of each individual thermal riser 810, may correspond to the distance between cooling plane 804 and the specific PCBA component(s) being cooled by that individual thermal riser 810. Thermal riser 810, while being less effective for heat transfer than thermal bridge 808, may have a lower manufacturing cost relative to thermal bridge 808. In some embodiments, such as when a lower-flux heat generating component on the PCBA is of a height such as to be capable of contacting cooling plane 804 directly, a thermal riser 810 may not be used for that heat generating component. In some embodiments, thermal riser 810 may further include contact pad 818. Contact pad 818 may be a thermally conductive, deformable material disposed at the PCBA contacting end of thermal riser 810. Contact pad 818 may help to ensure that thermal riser 810 (e.g., as well as each of the other thermal risers 810 and/or thermal bridges 808) receives sufficient contact for adequate heat transfer with the components of the PCBA, despite manufacturing tolerances that may cause variations in the relative positioning and orientation of the cooling plane, thermal risers 810 and/or thermal bridges 808, and/or the components of the PCBA. In some embodiments, one or more thermal bridges 808 and/or thermal risers 810 may be disposed and/or mechanically secured with corresponding components on the PCBA, and brought into contact with the cooling plane when the PCBA is assembled with heat transfer grid 800. In some embodiments, heat transfer grid 800 may include a split cooling frame where thermal bridges 808 and/or thermal risers 810 are attached to, or integral with, cooling planes of each contoured component of the split cooling frame. In another example, an open cooling frame may include thermal bridges 808 and/or thermal risers 810 that are attached to the exposed cooling elements.

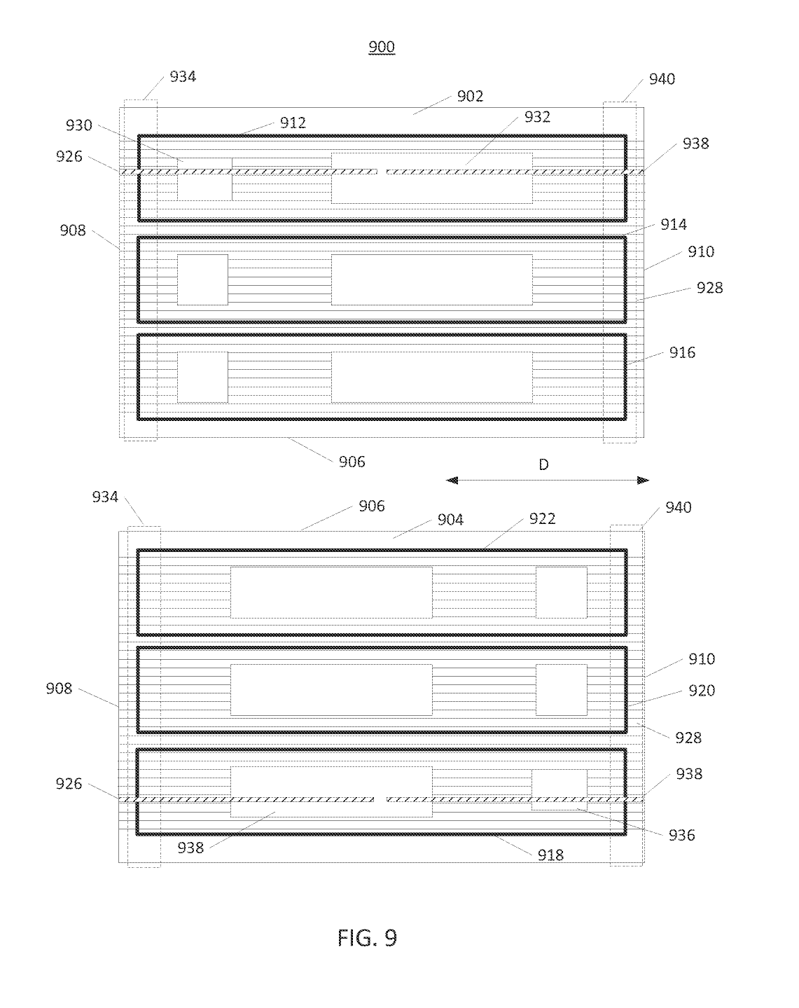

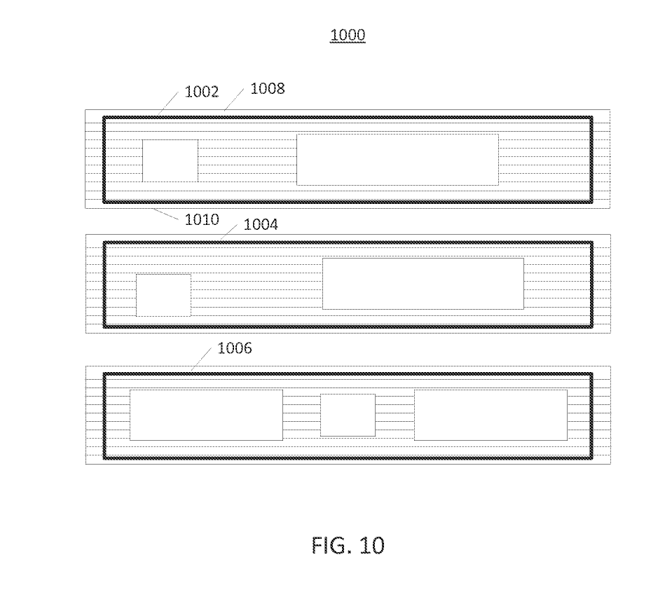

In some embodiments, the PCBAs may be secured on both cooling planes of a heat transfer grid in a manner that allocates heat flux of the PCBAs more efficiently and/or evenly among the cooling elements of the heat transfer grid. FIG. 9 shows an example heat transfer grid 900 in accordance with some embodiments. Heat transfer grid 900 may include cooling plane 902, and cooling plane 904 on the opposite side of cooling plane 902. Edges 906, 908, and 910 of heat transfer grid 900 are shown for both cooling plane 902 and cooling plane 904, to indicate the relative orientations shown for cooling plane 902 and cooling plane 904.

PCBAs 912, 914, and 916 may be disposed on cooling plane 902, and PCBAs 918, 920, and 922 may be disposed on cooling plane 904. Between cooling planes 902 and 904, a plurality of receptacles 928 may be defined. As discussed above, receptacles 928 may define a heat flow dimension D along the elongated length of the receptacles. Heat transfer grid 900 may further include a plurality of cooling elements disposed within receptacles 928, of which cooling elements 926 and 938 are shown.

PCBA 912 may include higher heat flux (e.g., processor) component 930 and lower heat flux component 932. As discussed above, cooling element 926 may be disposed within a receptacle 928 such that cooling element 926 can transfer heat along heat flow dimension D from higher heat flux component 930 to a heat exchange interface region 934 near edge 908.

PCBA 918 may be disposed on cooling plane 904 on the opposite side of heat transfer grid 900. PCBA 918 may include higher heat flux component 936 and lower heat flux component 938. In some embodiments, PCBAs 912 and 918 on opposite cooling planes of a heat transfer grid may be based on identical or similarly structured PCBA designs. When PCBAs are disposed on the two cooling planes, the cooling elements (e.g., cooling element 926) within associated receptacles that transfer heat for PCBA 912 may also transfer heat for PCBA 918. To disperse heat flux more evenly among cooling elements, the orientation of PCBA 918 may be mirrored or rotated 180 degrees relative to the orientation of PCBA 912. As such, cooling element 926 receives higher heat flux from higher heat flux component 930 of PCBA 912, and lower heat flux from lower heat flux component 938 of PCBA 918. In contrast, if the orientation of PCBA 918 is not mirrored or rotated 180 degrees relative to PCBA 912, then cooling element 926 would be required to transfer a higher amount of heat flux generated by both higher heat flux component 930 of PCBA 912 and higher heat flux component 936 of PCBA 918.

In another example, cooling element 938 may be disposed within a receptacle 928 such that cooling element 938 can transfer heat along heat flow dimension D from lower heat flux component 932 of PCBA 912 to a heat exchange interface region 940 near edge 910. Because PCBA 918 is mirrored with PCBA 912 as discussed above, cooling element 938 may also transfer heat from higher heat flux component 936 of PCBA 918, to heat exchange interface region 940 near edge 910. As such, neither cooling element 926 nor cooling element 938 is required to transfer heat from both higher heat flux components 930 and 936. Rather, heat flux is balanced or equalized, resulting in enhanced efficiency for both cooling element 926 and cooling element 938. Similarly, PCBAs on opposite sides of cooling planes that share receptacles or cooling elements may be mirrored. For example, PCBAs 914 and 920 may be mirrored with each other, and PCBAs 916 and 922 may be mirrored with each other.

FIG. 10 shows an example modular configurable heat transfer grid 1000 (or heat transfer grid 1000) in accordance with some embodiments. Heat transfer grid 1000 may include two or more modular cooling frames, such as modular cooling frames 1002-1006, that may be configured to be separable from each other. The separable modular cooling frames 1002-1006 may also be connected to each other (e.g., in any arrangement or order) to form heat transfer grid 1000. Modular cooling frames 1002-1006 may each define receptacles in which one or more cooling elements may be disposed as discussed herein. For example, where heat transfer grid 1000 includes three modular cooling frames 1002-1006, each of the modular cooling frames 1002-1006 may provide for a third of the total number of receptacles of heat transfer grid 1000 when the modular cooling frames are connected to each other. In some embodiments, one or more modular cooling frames 1002-1006 may include a split cooling frame, an open cooling frame, and/or a split open cooling frame. In that sense, the discussion herein regarding cooling frames may also be applicable to modular cooling frames.

Modular cooling frames 1002-1006 may be configured to be mechanically attached to each other using any suitable technique, such as screws, adhesives, etc. For example each modular cooling frame may include connectable edges 1008 and 1010 (e.g., edges parallel to the heat flow dimension of the receptacles and cooling elements) that can be brought in contact and/or connected with a connectable edge 1008 or 1010 of a second modular cooling frame, to form an assembled heat transfer grid 1000.

In some embodiments, each of the modular cooling frames may be secured with one or more PCBAs on each of two cooling planes (e.g., one cooling plane on each of two opposing sides of a modular cooling frame). The PCBAs on opposite sides of each modular cooling frame may be of similar or identical design, and/or mirrored for more evenly distributed heat flux, as discussed above in connection with FIG. 9. An assembled heat transfer grid 1000 may include a plurality of modular cooling frames that may differ from one another in configuration. For example, each of the modular cooling frames 1002-1006 shown in FIG. 10 may be secured with one PCBA on the side shown in FIG. 10, and the PCBA that is secured to each one of these modular cooling frames may differ in configuration from the PCBAs that are secured to the other two of these modular cooling frames. Accordingly, each one of the three modular cooling frames 1002-1006 may differ from the others in configuration of component interface regions, as dictated by the configurations of the PCBAs secured with these modular cooling frames. A plurality of modular cooling frames included in heat transfer grid 1000 may further differ from one another in configurations of cooling elements, thermal keys, thermal bridges, and/or thermal risers, depending on the specific locations and features (e.g., height) of the components of each PCBA, as discussed herein.

Modular configurable heat transfer grids may provide for greater configurability or reconfigurability, relative to other types of configurable heat transfer grids. For example, in some embodiments, a modular configurable heat transfer grid may be created for a plurality of PCBAs that differ from one another in configuration, by selecting for each of the PCBAs a modular cooling frame that is preconfigured to optimize heat transfer from that PCBA. Each PCBA may then be secured with the corresponding modular cooling frame (e.g., on a cooling plane). Subsequent to or prior to attachment to the PCBAs, the modular cooling frames may be connected with each other to form the modular configurable heat transfer grid

Many modifications and other embodiments will come to mind to one skilled in the art to which these embodiments pertain, having the benefit of the teachings presented in the foregoing descriptions and the associated drawings. Therefore, it is to be understood that embodiments and implementations are not to be limited to the specific example embodiments disclosed, and that modifications and other embodiments are intended to be included within the scope of the appended claims. Although specific terms are employed herein, they are used in a generic and descriptive sense only, and not for purposes of limitation.

That which is claimed:

1. A self-contained heat transfer grid, comprising:
a cooling frame, the cooling frame defining a first cooling plane and a second cooling plane and having a first outer end and a second outer end, each of the first outer end and the second outer end including one or more apertures that define a plurality of receptacles between the first and second cooling planes; and
one or more removable cooling elements, the one or more cooling elements having an elongated shape and positionable within one or more of the plurality of receptacles.

2. The heat transfer grid of claim 1 further including at least one external heat exchange interface region on one of the first or second cooling planes; and wherein a first one of the one or more cooling elements positioned within one of the plurality of receptacles extends from one of the first or second outer ends to the external heat exchange interface region.

3. The heat transfer grid of claim 1, wherein:
each of the plurality of receptacles has a cross sectional shape that is substantially the same as a cross sectional shape of the one or more removable cooling elements, and includes an elongated shape defining an elongated direction; and
the cooling frame includes at least two receptacles, and the one or more removable cooling elements are positioned in fewer than all of the at least two receptacles.

4. The heat transfer grid of claim 1, wherein:
the heat transfer grid includes at least three external heat exchange interface regions, and at least a first one of the external heat exchange interface regions is adjacent to and parallel to the first outer end; and
at least a second one of the external heat exchange interface regions is adjacent to and parallel to the second outer end.

5. The heat transfer grid of claim 1, wherein the first cooling element does not extend from the first outer end to the second outer end of the cooling frame when positioned within the receptacle.

6. The heat transfer grid of claim 1, wherein the first cooling element is positioned within one of the receptacles and extends only part way from the first outer end of the cooling frame to the second outer end, and a second one of the one or more cooling elements is positioned within the same receptacle as the first cooling element and extends only part way from the second outer end of the cooling frame to the first outer end; and wherein the first and second cooling elements do not overlap.

7. The heat transfer grid of claim 1, wherein the first cooling element when positioned within one of the receptacles extends from an external heat exchange interface region to a component thermal interface region of the heat transfer grid.

8. A heat transfer grid, comprising:
a split cooling frame, the split cooling frame including a first contoured component and a second contoured component; the first contoured component and the second contoured component are configured to be removably placed together, the first contoured component including a plurality of channels; the second contoured component including a plurality of channels, the channels in the first contoured component and the second contoured component arranged such that when the first contoured component and the second contoured component are placed together, the channels form elongated receptacles; and
one or more cooling elements, the one or more cooling elements having an elongated shape, and wherein the plurality of channels of at least one of the first contoured component and the second contoured component are configured to receive the one or more cooling elements when the first contoured component is separated from the second contoured component such that the one or more cooling elements can be disposed in one or more receptacles when the first contoured component and the second contoured component are placed together.

9. The heat transfer grid of claim 8, wherein:
the elongated receptacles have a cross sectional shape that is substantially the same as a cross sectional shape of the one or more removable cooling elements and include an elongated shape defining an elongated direction;
the receptacles collectively span part or all of a width of the cooling frame, the width defined perpendicular to the elongated direction; and
the one or more cooling elements are positioned in fewer than all of the elongated receptacles.

10. The heat transfer grid of claim 8, wherein the channels include channel surfaces and further comprising a thermal interface material disposed between at least one of the one or more cooling elements and the channel surfaces.

11. The heat transfer grid of claim 8, wherein the split cooling frame includes a first outer end and a second outer end and wherein a first cooling element of the one or more cooling elements, when received into one of the receptacles, does not extend from the first outer end to the second outer end of the split cooling frame.

12. The heat transfer grid of claim 8, wherein a first cooling element and a second cooling element of the one or more cooling elements are received into one of the elongated receptacles.

13. The heat transfer grid of claim 8, wherein:
the first contoured component includes a first cooling plane including an external heat exchange interface region and a component thermal interface region; and
a first cooling element of the one or more cooling elements extends from the external heat exchange interface region to the component thermal interface region.

14. The heat transfer grid of claim 8, wherein at least one receptacle associated with a non-component thermal interface region of the heat transfer grid does not include a cooling element.

15. A heat transfer grid, comprising:
an open cooling frame including:
a first element guide defining a first outer edge of the open cooling frame, the first element guide including one or more apertures; and
a second element guide defining a second outer edge of the open cooling frame, the second element guide including one or more apertures, the apertures of the first and second element guides are collinear; and
one or more cooling elements each having an elongated shape and each disposed in an aperture of at least one of the first element guide and the second element guide.

16. The heat transfer grid of claim 15, wherein:
the open cooling frame further includes one or more guide supports, the guide supports connect the first element guide and the second element guide, and
the first element guide, the second element guide, and the one or more guide supports of the open cooling frame define a cooling element access region where the one or more cooling elements are exposed by the open cooling frame when the one or more cooling elements are each disposed in the aperture of at least one of the first element guide and the second element guide; and
the one or more cooling elements include two or more cooling elements that define a cooling plane at the cooling element access region.

17. The heat transfer grid of claim 16 further comprising an adjustable element guide configured to be connected to the one or more guide supports at variable locations between the first element guide and the second element guide, the adjustable element guide including one or more apertures that are collinear with the apertures of the first and second element guides.

18. The heat transfer grid of claim 15, wherein at least one of the one or more cooling elements includes a flattened circular cross section.

19. The heat transfer grid of claim 15, wherein at least one of the one or more cooling elements extends beyond at least one of the first outer edge and the second outer edge of the open cooling frame.

20. The heat transfer grid of claim 15, wherein at least one of the one or more cooling elements does not extend from the first outer end to the second outer end of the open cooling frame.

21. The heat transfer grid of claim 15, wherein at least one of the one or more cooling elements extends approximately half the distance from the first outer edge to the second outer edge of the cooling frame.

22. The heat transfer grid of claim 15, wherein a first one of the one or more cooling elements includes a heat pipe disposed within a first aperture of the first element guide, and a second one of the one or more cooling elements includes a heat spreader disposed within a second aperture of the first element guide, the first aperture being adjacent to the second aperture.

23. The heat transfer grid of claim 15, wherein a first one of the one or more cooling elements includes a heat pipe disposed within a first aperture of the first element guide, and a second one of the one or more cooling elements includes a heat spreader disposed within a second aperture of the first element guide, such that the heat pipe is associated with a component thermal interface region of the heat transfer grid, and the heat spreader is associated with a non-component thermal interface region of the heat transfer grid.

24. A method of configuring a heat transfer grid, comprising:
providing a heat transfer grid defining a plurality of receptacles, each receptacle configured to receive a cooling element;
determining a component interface region of the heat transfer grid;
determining an external heat exchange interface region of the heat transfer grid; and
disposing a cooling element within a receptacle extending from the component interface region to the external heat exchange interface region.

25. The method of claim 24, wherein:
the receptacle is accessible via an aperture at an outer end of a cooling frame of the heat transfer grid; and
disposing the cooling element within the receptacle includes disposing the cooling element within the receptacle through the aperture.

26. The method of claim 24, wherein disposing the cooling element within the receptacle includes:
separating a first contoured component of the cooling frame from a second contoured component of the cooling frame, the first contoured component and the second contoured component are configured to be removably placed together, the first contoured component including a plurality of channels; the second contoured component including a plurality of channels, the channels in the first contoured component and the second contoured component arranged such that when the first contoured component and the second contoured component are placed together, the channels form the plurality of receptacles;
disposing the cooling element within a channel of at least one of the first contoured component and the second contoured component; and
subsequent to disposing the cooling element within the channel, joining the first contoured component with the second contoured component to form the receptacle.

27. The method of claim 26, wherein the channels include channel surfaces and further comprising, prior to joining the first contoured component with the second contoured component, disposing a thermal interface material between the cooling element and the channel surfaces.

28. The method of claim 24 further comprising disposing a second cooling element within a second receptacle of the plurality of receptacles, wherein the first cooling element is a heat pipe and the second cooling element is a heat spreader.

29. The method of claim 24 further comprising:
determining a non-component interface region of the heat transfer grid; and
removing a second cooling element from a second receptacle associated with the non-component interface region.

30. The method of claim 29 further comprising, subsequent to removing the second cooling element from the second receptacle associated with the non-component interface region, disposing a third cooling element within the second receptacle, wherein the second cooling element is a heat pipe and the third cooling element is a heat spreader.

31. The method of claim 24, wherein determining the component interface region of the heat transfer grid includes:
securing a printed circuit board assembly (PCBA) to the heat transfer grid; and
determining the component interface region as a region of the heat transfer grid in thermal contact with a component of the PCBA when the PCBA is secured to the heat transfer grid.

32. The method of claim 31 further comprising:
determining whether the cooling element can be removed from the receptacle while maintaining sufficient cooling for the PCBA by the heat transfer grid; and
in response to determining that removing the cooling element would result in sufficient cooling, removing the cooling element from the receptacle.

33. The method of claim 31 further comprising:
determining whether the cooling element should be added to the receptacle to achieve sufficient cooling for the PCBA by the heat transfer grid; and
in response to determining that the cooling element should be added to achieve sufficient cooling, disposing the cooling element within the receptacle.
